(19) United States
(12) Patent Application Publication
(10) Pub. No.: US 2025/0155472 A1
(43) Pub. Date: May 15, 2025

(54) TEST FIXTURE ASSEMBLY

(71) Applicant: Universal Scientific Industrial (Shanghai) Co., Ltd., Shanghai (CN)

(72) Inventors: HAO LIANG HUNG, Shanghai (CN); CHUN YING HUANG, Shanghai (CN); KUANG TING CHI, Shanghai (CN); YU CHENG LIU, Shanghai (CN)

(21) Appl. No.: 18/939,540

(22) Filed: Nov. 7, 2024

(30) Foreign Application Priority Data
Nov. 15, 2023 (CN) 202311525304.5

(51) Int. Cl. G01R 1/067; G01R 1/04

(52) U.S. Cl. CPC G01R 1/06772; G01R 1/0416

(57) ABSTRACT

A test fixture assembly is for performing a test of a DUT (Device under Test), the DUT includes a plurality of pins exposed on a surface of the DUT, and the test fixture assembly includes a circuit board and a socket unit. The circuit board includes a plurality of test pads, which are exposed on a surface of the circuit board. The socket unit includes a socket base and a plurality of socket probes, which are inserted through the socket base. A first end and a second end of each of the socket probes are respectively exposed on two opposite surfaces of the socket base. Each of the test pads, a corresponding one of the socket probes and a corresponding one of the pins are configured to be linearly arranged along a socket probe direction.

### RELATED APPLICATIONS

This application claims priority to China Application Serial Number 202311525304.5, filed Nov. 15, 2023, which is herein incorporated by reference.

### BACKGROUND

### Technical Field

The present disclosure relates to a test fixture assembly. More particularly, the present disclosure relates to a test fixture assembly including a plurality of socket probes.

### Description of Related Art

Driven by human beings' pursuit of convenient life, various wireless communication systems and their radio frequency technologies have been developed. For example, the 5G millimeter wave (mmWave) technology is raised in recent years, and the quality verification for the 5G millimeter wave antenna package (Antenna on Package, AoP) module has become an important part. However, for verifying the module in the conventional technology, it is usually necessary to make a separate carrier board with a larger area for electrically connecting the pins of the module to the test equipment through the connector on the carrier board. In this way, it is bound to delay the verification time and cost of the module.

Therefore, how to quickly detect defects in modules or components therein while saving testing time and cost has become an important issue in today's market.

### SUMMARY

According to one aspect of the present disclosure, a test fixture assembly is for performing a test of a DUT (Device under Test), the DUT includes a plurality of pins exposed on a surface of the DUT, and the test fixture assembly includes a circuit board and a socket unit. The circuit board includes a plurality of test pads, which are exposed on a surface of the circuit board. The socket unit includes a socket base and a plurality of socket probes, which are inserted through the socket base. A first end and a second end of each of the socket probes are respectively exposed on two opposite surfaces of the socket base. The first ends are configured to be electrically connected to the pins, respectively. The second ends are electrically connected to the test pads, respectively. Each of the test pads, a corresponding one of the socket probes and a corresponding one of the pins are configured to be linearly arranged along a socket probe direction.

### BRIEF DESCRIPTION OF THE DRAWINGS

The present disclosure can be more fully understood by reading the following detailed description of the embodiment, with reference made to the accompanying drawings as follows:

FIG. 1 is a three-dimensional view of a test fixture assembly according to an embodiment of the present disclosure.

FIG. 2 is an exploded view of the test fixture assembly in FIG. 1 and a DUT.

FIG. 3 is an exploded view of a socket unit of the test fixture assembly in FIG. 1.

FIG. 4 is a top view of the socket unit of the test fixture assembly in FIG. 1.

FIG. 5 is a cross-sectional view along line 5-5 in FIG. 4.

FIG. 6 is a schematic view of a usage state of the test fixture assembly in FIG. 1.

FIG. 7 is a schematic view of a test result applying the test fixture assembly in FIG. 1.

FIG. 8 is a schematic view of another test result applying the test fixture assembly in FIG. 1.

### DETAILED DESCRIPTION

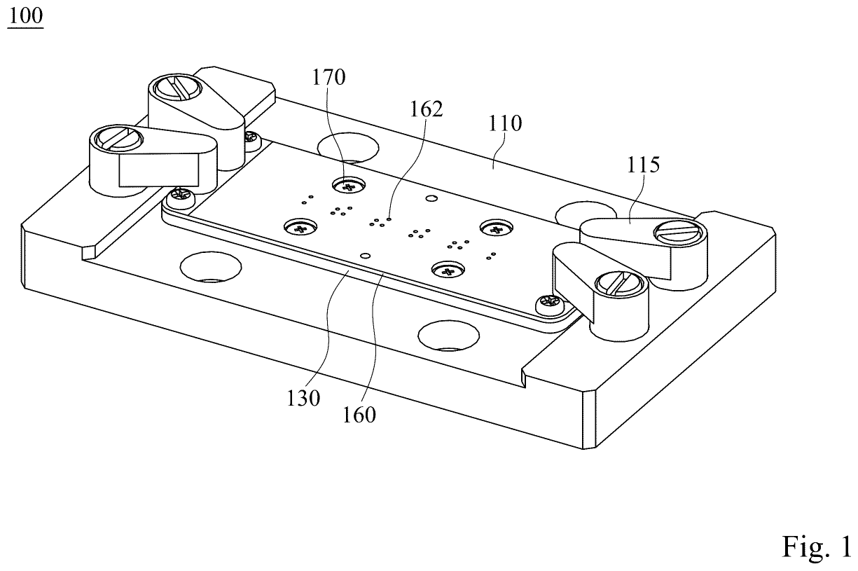

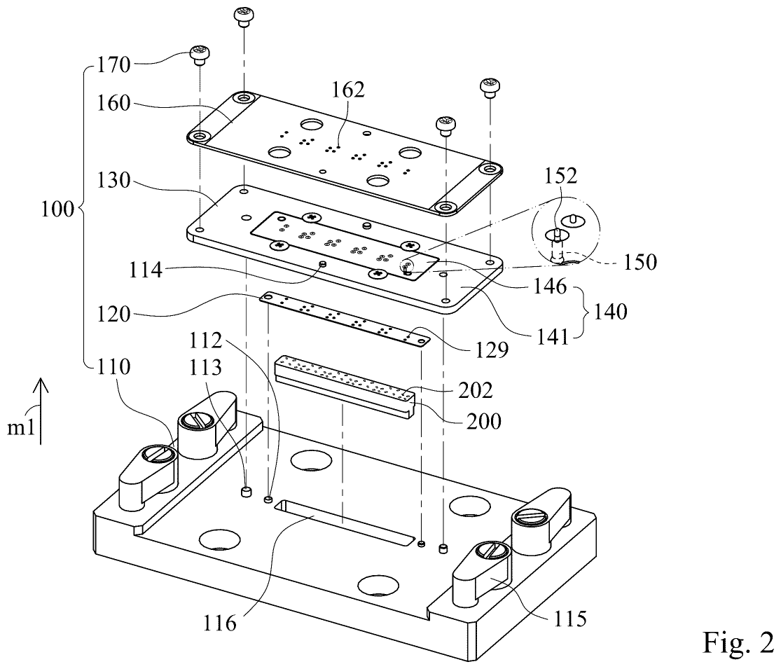

FIG. 1 is a three-dimensional view of a test fixture assembly 100 according to an embodiment of the present disclosure, and FIG. 2 is an exploded view of the test fixture assembly 100 in FIG. 1 and a DUT (Device under Test) 200. With reference to FIG. 1 and FIG. 2, the test fixture assembly 100 is for performing a test of the DUT 200. The DUT 200 includes a plurality of pins 202 exposed on a surface of the DUT 200. The test fixture assembly 100 includes a circuit board (substrate) 160 and a socket unit 130. The circuit board 160 includes a plurality of test pads 162 and a plurality of fixture pads (not shown in drawings), which are made of metal material. The test pads 162 and the fixture pads are exposed on two opposite surfaces, respectively, of the circuit board 160, and the test pads 162 and the fixture pads are electrically connected, respectively. Furthermore, the pins 202 of the DUT 200 may be in the form of conductive patches or conductive frames. The test pads 162 are configured for contacting the test equipment probes and electrically connecting to the test equipment (e.g., a network analyzer) through the test equipment probes. The circuit board 160 may be a four-layer stacked circuit board, and is not limited thereto.

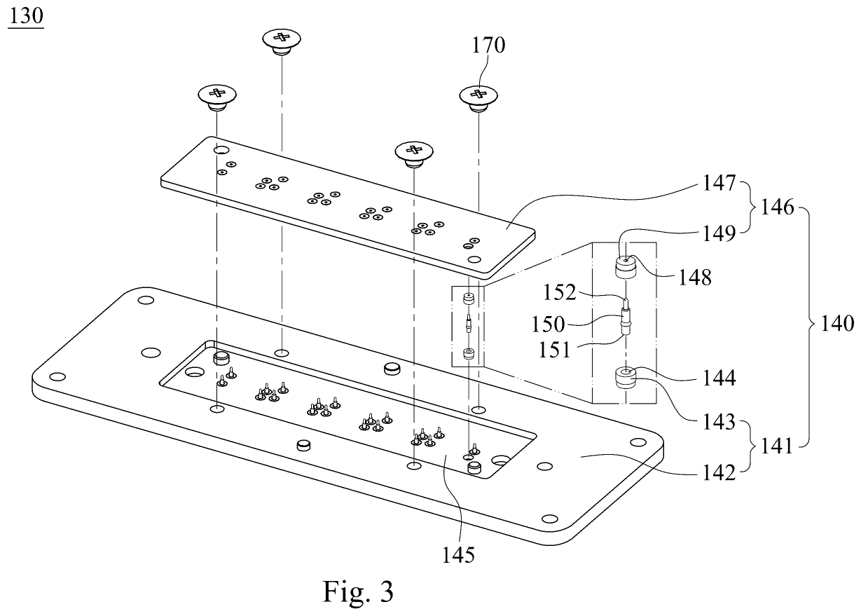

FIG. 3 is an exploded view of a socket unit 130 of the test fixture assembly 100 in FIG. 1. With reference to FIG. 1 to FIG. 3, the socket unit 130 includes a socket base 140 and a plurality of socket probes 150, which are inserted through the socket base 140. A first end 151 and a second end 152 of each of the socket probes 150 are respectively exposed on two opposite surfaces of the socket base 140. The first ends 151 are configured to be electrically connected to the pins 202 of the DUT 200, respectively. The second ends 152 are in contact with the fixture pads, respectively, of the circuit board 160, so as to be electrically connected to the test pads 162, respectively. Each of the test pads 162, a corresponding one of the socket probes 150 and a corresponding one of the pins 202 are configured to be linearly arranged along a socket probe direction m1, as shown in FIG. 2. Therefore, the test points (i.e., the test pads 162) are designed on the top layer of the circuit board 160, and each electrical connection path from one of the test pads 162, one of the socket probes 150 to one of the pins 202 of the DUT 200 forming an extension of the test equipment probe can achieve the purpose of the probing measurement of the test fixture assembly 100. That is, the test fixture assembly 100 and the DUT 200 are placed on the probe station, and then the test can be performed by causing the test equipment probes to automatically or manually touch the test pads 162. Furthermore, the test fixture assembly 100 is beneficial to accurately obtain optimized RF (Radio Frequency) routings and material properties (e.g., a dielectric constant, Dk) of the circuit board 160 by the electromagnetic simulation software in advance, so as to help to entirely design the test fixture assembly 100.

In detail, with reference to FIG. 1 and FIG. 2, the test fixture assembly 100 may further include a guide plate 110. The guide plate 110 includes a groove 116, which is configured for accommodating the DUT 200. The pins 202 of the DUT 200 face an outward direction of the guide plate 110. Therefore, it is advantageous in improving the usage convenience of the test fixture assembly 100, and increasing the test accuracy by stable assembling of the test fixture assembly 100.

With reference to FIG. 2, the test fixture assembly 100 may further include a gasket (spacer, isolation sheet) 120, which is configured for being connected between the DUT 200 and the socket unit 130 and includes a plurality of openings 129. The socket probes 150 are inserted through the openings 129, respectively, and the openings 129 are configured for the first ends 151 being in contact with and connected to the pins 202, respectively. Therefore, the gasket 120 is added above the DUT 200 to form a clear area (non-metallic, dielectric area) between the test fixture assembly 100 and the DUT 200 to cooperate with the circuit board 160, the socket unit 130 and the guide plate 110 to form the overall stacked design of the test fixture assembly 100. This allows each electrical connection path from one of the test pads 162, one of the socket probes 150 to one of the pins 202 to form an extension of the test equipment probe to contact the pin 202.

The gasket 120 may be made of a plastic material and configured for impedance matching of the DUT 200. Therefore, based on the stack-up design considerations of the test fixture assembly 100, the impedance matching of the DUT 200 can be achieved through the material characteristics, area size and thickness of the gasket 120. Moreover, in the design stage of the test fixture assembly 100, the electromagnetic simulation software can be used to obtain optimized design based on impedance matching, so that the test fixture assembly 100 can be used to realize the electrical characteristics of the DUT 200, which is subsequently assembled into the product.

Specifically, with reference to FIG. 1 to FIG. 3, the circuit board 160, the socket unit 130, the gasket 120 and guide plate 110 of the test fixture assembly 100 of the embodiment are stacked in sequence from top to bottom. The groove 116 of the guide plate 110 is configured to accommodate the DUT 200, and the bottom surface of the gasket 120 is configured to contact the DUT 200. In addition, the guide plate 110 may further include a plurality of pressing rods 115 and a plurality of positioning protrusions 112, 113. The base body 142 of the socket base 140 may include a plurality of positioning protrusions 114. The positioning protrusions 112 are fitted into (engaged with) the opening of the gasket 120, the positioning protrusions 113 are fitted into the recessed hole of the base body 142, and the positioning protrusions 114 are fitted into the opening of the circuit board 160. The pressing rods 115 press against the top surface of the circuit board 160, and the test fixture assembly 100 is fixed with a plurality of screws 170. Therefore, the components of the test fixture assembly 100 are stably stacked and electrically connected.

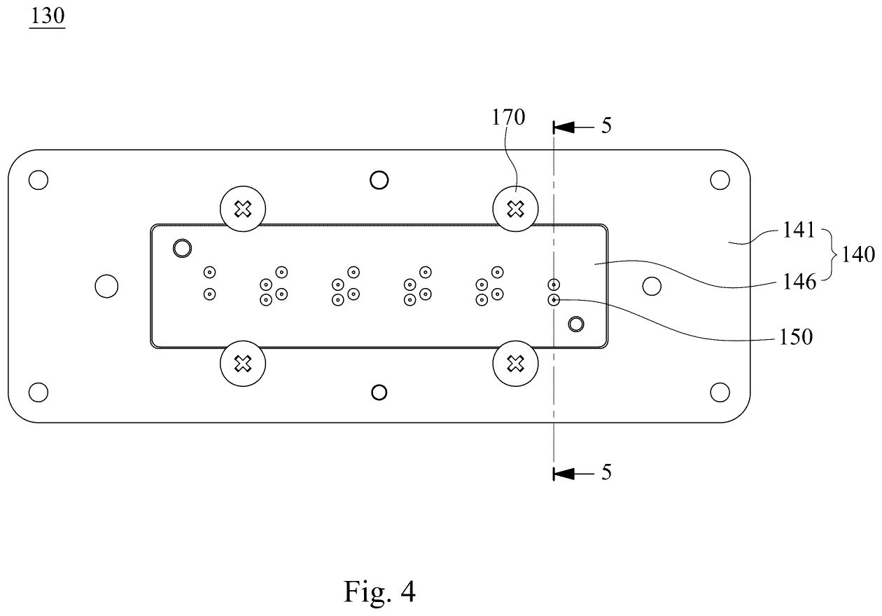

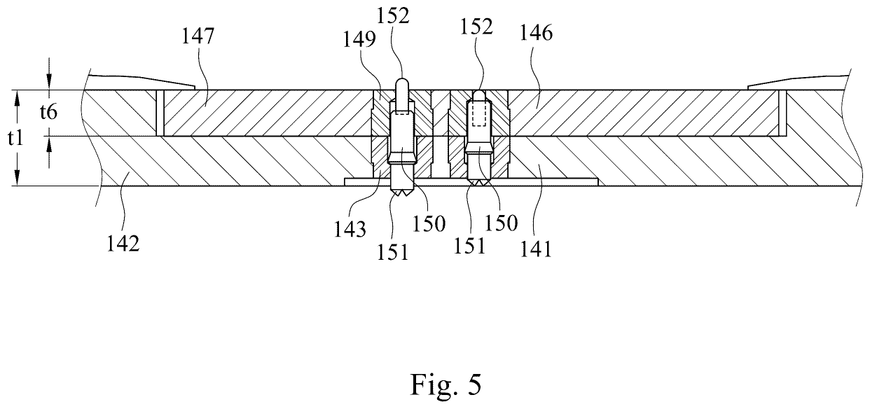

FIG. 4 is a top view of the socket unit 130 of the test fixture assembly 100 in FIG. 1, and FIG. 5 is a cross-sectional view along line 5-5 in FIG. 4. With reference to FIG. 2 to FIG. 5, the socket base 140 may include a base member 141 and a cover member 146. Each of the socket probes 150 is sequentially inserted in a base opening 144 of the base member 141 and a cover opening 148 of the cover member 146 along the socket probe direction m1, and each of the socket probes 150 is an elastic probe (e.g., a pogo pin). As shown in FIG. 5, the left half of FIG. 5 shows the state that the socket unit 130 has not been assembled into the test fixture assembly 100, and at this time, the first end 151 and the second end 152 of each of the socket probes 150 respectively protrude from the two opposite sides of the socket base 140; the right half of FIG. 5 shows the state that the socket unit 130 is stacked and assembled into the test fixture assembly 100, and at this time, the first end 151 and the second end 152 of each of the socket probes 150 are respectively exposed on and aligned with the two opposite sides of the socket base 140. Therefore, this helps to ensure that the first end 151 and the second end 152 of each of the socket probes 150 are firmly electrically connected to the corresponding pin 202 and the corresponding test pad 162, respectively.

The cover member 146 may be accommodated in a groove 145 of the base member 141, and a surface of the cover member 146 facing the circuit board 160 is aligned with a surface of the base member 141 facing the circuit board 160, as shown in FIG. 2 and FIG. 5. Therefore, the cover member 146 and the base member 141 form a flat surface, so as to simultaneously achieve the stacking and assembling stability among the components of the test fixture assembly 100 and the installing stability of the socket probe 150.

With reference to FIG. 5, a ratio of a maximum thickness t1 of the base member 141 to a thickness t6 of the cover member 146 may be between 1.5 and 2.5. Therefore, it is beneficial to enhance the installing stability of the socket probes 150. In the embodiment, the maximum thickness t1 of the base member 141 is 1.25 mm, the thickness t6 of the cover member 146 is 0.6 mm, and the aforementioned ratio is 2.08.

With reference to FIG. 3 and FIG. 5, the base member 141 may include the base body 142 and a plurality of base bushes 143. Each of the base bushes 143 is fitted with a wall forming an opening of the base body 142, and each of the base openings 144 is formed by an inner annular wall of one of the base bushes 143. The cover member 146 may include a cover body 147 and a plurality of cover bushes 149. Each of the cover bushes 149 is fitted with a wall forming an opening of the cover body 147, and each of the cover openings 148 is formed by an inner annular wall of one of the cover bushes 149. Each of the base body 142 and the cover body 147 is made of a metal material (e.g., a cupper material), and each of the base bushes 143 and the cover bushes 149 is made of an elastic material. Therefore, it helps to fix the position of each of socket probes 150 to avoid slipping.

With reference to FIG. 2, the DUT 200 may further include a plurality of antenna elements electrically connected to the pins 202 at the inner part of the DUT 200 and having an operating frequency between 20 GHz and 100 GHz. The DUT 200 may specifically be an antenna module, an antenna array module or an antenna package module. Therefore, the conventional verification of the antenna module is usually only to verify the entire antenna module. If it is required to verify a single antenna element of the antenna module, it needs to make a separate carrier board with a larger area, solder the corresponding pins of the antenna element to the carrier board, and then S-parameters and other measurements are performed through larger test pads on the carrier board or additional connectors soldered on the carrier board. This will inevitably delay the verification time and increase the cost of the antenna module. According to the test fixture assembly 100 of the present disclosure, the extensions of the test equipment probes are formed by the electrical connection paths from the test pads 162 of the circuit board 160, the socket probes 150 of the socket unit 130 to the pins 202 of the DUT 200, so that the probe-type test fixture assembly 100 helps to quickly detect defects of the antenna element body. Furthermore, it also helps to control the quality of incoming materials, so as to quickly respond to and ask the suppliers for improvements of the problems.

Each of the antenna elements of the DUT 200 may be a dielectric resonator antenna (DRA) and is electrically connected to two of the pins 202 at the inner part of the DUT 200. Therefore, the dielectric resonator antenna helps to improve the antenna efficiency in the millimeter wave band. However, each dielectric resonator antenna has a total of two pins of a vertical polarization pin (vertical polarization port) and a horizontal polarization pin (horizontal polarization port). This increases the time, cost and difficulty of the conventional technology to verify a single antenna element in the antenna module. The test fixture assembly 100 according to the present disclosure helps to improve the verification efficiency and accuracy of the DUT 200 including the dielectric resonator antennas. Moreover, when the test result of the DUT 200 is abnormal, further analysis can be performed on an abnormal one of the pins 202 and its corresponding antenna element to confirm whether there is a foreign object on the surface of the pin 202 or whether there is a manufacturing defect inside the DUT 200.

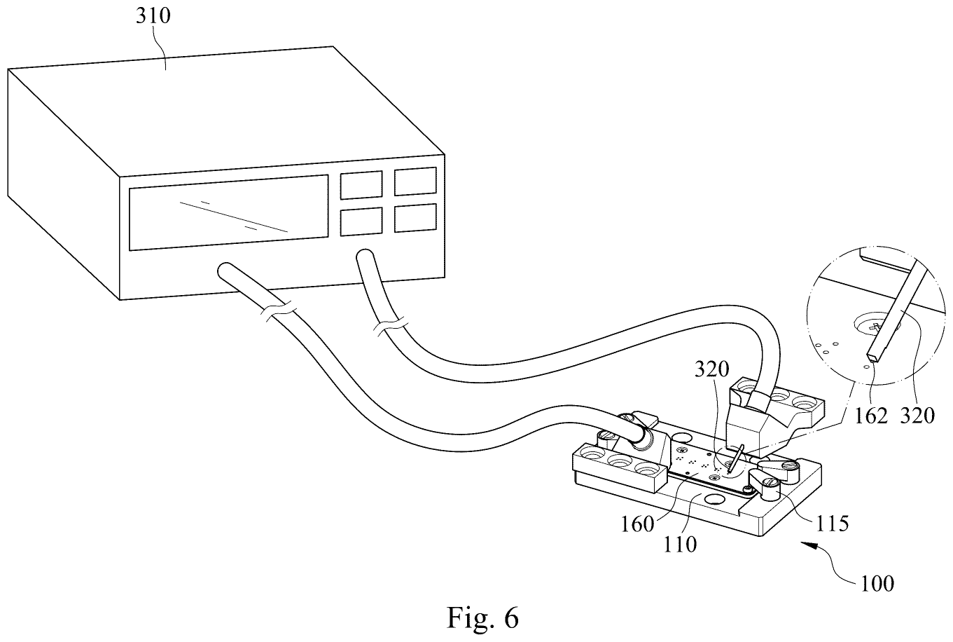

FIG. 6 is a schematic view of a usage state of the test fixture assembly 100 in FIG. 1. With reference to FIG. 6, the test fixture assembly 100 and the DUT 200 can be placed on the probe station (not shown in drawings), and the test equipment 310 is electrically connected to the test equipment probes 320 via cables. The test equipment probes 320 may be in the type of SG or GSG. The S ports of the test equipment probes 320 contact the test pads 162 of the test fixture assembly 100 to be electrically connected to the pins 202 of the DUT 200, and the G ports of the test equipment probes 320 may contact and may be electrically connected to the ground pad on the circuit board 160, so as to detect the DUT 200 and the antenna element thereof.

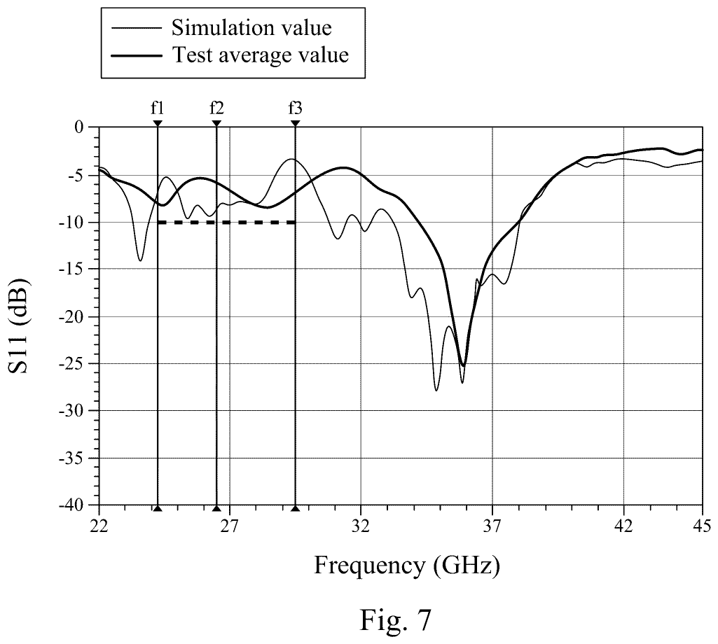

FIG. 7 is a schematic view of a test result applying the test fixture assembly 100 in FIG. 1. With reference to FIG. 7, FIG. 7 shows the simulation value simulated by the electromagnetic simulation software for one of the pins 202 of the DUT 200 based on the characteristics of the test fixture assembly 100 and the DUT 200, and shows the test average value of multiple normal test results. When the test value of the S11 parameter of the said pin 202 in a test has significantly difference between the simulation value and the test average value at all frequencies or a frequency band (e.g., the frequency band formed by 24.25 GHZ, 26.50 GHZ, 29.50 GHz of the frequencies f1, f2, f3, respectively), it means that there is a defective phenomenon in the structure related to the said pin 202 and further analysis is required.

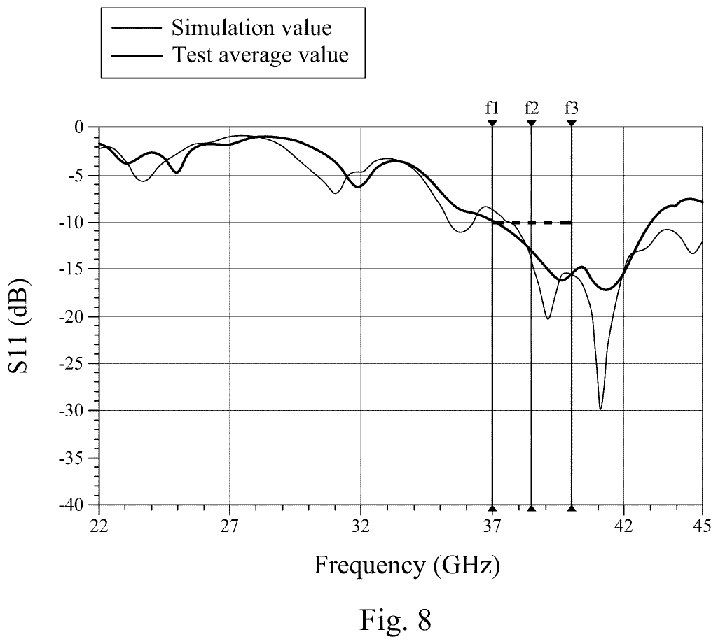

FIG. 8 is a schematic view of another test result applying the test fixture assembly 100 in FIG. 1. With reference to FIG. 8, FIG. 8 shows the simulation value simulated by the electromagnetic simulation software for another of the pins 202 of the DUT 200 based on the characteristics of the test fixture assembly 100 and the DUT 200, and shows the test average value of multiple normal test results. When the test value of the S11 parameter of the said another pin 202 in a test has significantly difference between the simulation value and the test average value at all frequencies or a frequency band (e.g., the frequency band formed by 37.00 GHZ, 38.50 GHZ, 40.00 GHz of the frequencies f1, f2, f3, respectively), it means that there is a defective phenomenon in the structure related to the said another pin 202 and further analysis is required.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A test fixture assembly, for performing a test of a DUT (Device under Test), the DUT comprising a plurality of pins exposed on a surface of the DUT, the test fixture assembly comprising:
a circuit board comprising a plurality of test pads, which are exposed on a surface of the circuit board; and
a socket unit comprising a socket base and a plurality of socket probes, which are inserted through the socket base, wherein a first end and a second end of each of the socket probes are respectively exposed on two opposite surfaces of the socket base, the first ends are configured to be electrically connected to the pins, respectively, and the second ends are electrically connected to the test pads, respectively;
wherein each of the test pads, a corresponding one of the socket probes and a corresponding one of the pins are configured to be linearly arranged along a socket probe direction.

2. The test fixture assembly of claim 1, wherein the socket base comprises a base member and a cover member, each of the socket probes is sequentially inserted in a base opening of the base member and a cover opening of the cover member along the socket probe direction, and each of the socket probes is an elastic probe.

3. The test fixture assembly of claim 2, wherein the cover member is accommodated in a groove of the base member, and a surface of the cover member facing the circuit board is aligned with a surface of the base member facing the circuit board.

4. The test fixture assembly of claim 3, wherein a ratio of a maximum thickness of the base member to a thickness of the cover member is between 1.5 and 2.5.

5. The test fixture assembly of claim 2, wherein the base member comprises a base body and a plurality of base bushes, each of the base bushes is fitted with a wall forming an opening of the base body, and each of the base openings is formed by an inner annular wall of one of the base bushes;
wherein the cover member comprises a cover body and a plurality of cover bushes, each of the cover bushes is fitted with a wall forming an opening of the cover body, each of the cover openings is formed by an inner annular wall of one of the cover bushes, and each of the base bushes and the cover bushes is made of an elastic material.

6. The test fixture assembly of claim 1, further comprising:
a gasket configured for being connected between the DUT and the socket unit and comprising a plurality of openings, wherein the socket probes are inserted through the openings, respectively, and the openings are configured for the first ends being in contact with the pins, respectively.

7. The test fixture assembly of claim 6, wherein the gasket is made of a plastic material and configured for impedance matching of the DUT.

8. The test fixture assembly of claim 1, further comprising:
a guide plate comprising a groove configured for accommodating the DUT, wherein the pins face an outward direction of the guide plate.

9. The test fixture assembly of claim 1, wherein the DUT further comprises a plurality of antenna elements electrically connected to the pins and have an operating frequency between 20 GHz and 100 GHz.

10. The test fixture assembly of claim 9, wherein each of the antenna elements is a dielectric resonator antenna and is electrically connected to two of the pins.
